(19) United States
(12) Patent Application Publication
(10) Pub. No.: US 2014/0127483 A1
(43) Pub. Date: May 8, 2014

(54) COPPER-CLAD LAMINATE. METHOD FOR MANUFACTURING THE SAME, AND PRINTED CIRCUIT BOARD INCLUDING THE SAME

(71) Applicant: SAMSUNG ELECTRO-MECHANICS CO., LTD., Suwon (KR)

(72) Inventors: Jin Seok Moon, Suwon (KR); Sa Yong Lee, Suwon (KR); Seong Hyun Yoo, Suwon (KR)

(73) Assignee: SAMSUNG ELECTRO-MECHANICS CO., LTD., Suwon (KR)

(21) Appl. No.: 13/761,613

(22) Filed: Feb. 7, 2013

(30) Foreign Application Priority Data
Nov. 8, 2012 (KR) 10-2012-0126108

(51) Int. Cl. H05K 3/00; B32B 3/10; B32B 17/04; H05K 1/03; B32B 7/02; B32B 15/08

(52) U.S. Cl. CPC H05K 3/0011; B32B 7/02; B32B 15/08; B32B 17/04; H05K 1/036; B32B 3/10
USPC 428/209; 29/825; 428/213

(57) ABSTRACT

Disclosed herein are a method for manufacturing a copper-clad laminate (CCL) for a printed circuit board, a CCL manufactured by the method, and a printed circuit board having the CCL applied thereto, the method including: forming a first resin coated copper foil (first RCC foil) and a second resin coated copper foil (second RCC foil) by coating an insulating composition on one surface of each of two copper foils to form insulating layers, respectively, followed by drying of the first and second RCC foils; forming a copper-clad laminate (CCL) by laminating and pressing the first RCC foil and the second RCC foil while the insulating layers of the first and second RCC foils face each other and a glass fiber is placed therebetween; and hardening the copper-clad laminate.

### CROSS REFERENCE TO RELATED APPLICATION

This application claims the benefit of Korean Patent Application No. 10-0126108, filed on Nov. 8, 2012, entitled “Copper-Clad Laminate, Method for Manufacturing the Same, and Printed Circuit Board Including the Same”, which is hereby incorporated by reference in its entirety into this application.

### BACKGROUND OF THE INVENTION

1. Technical Field

The present invention relates to a copper-clad laminate, a method for manufacturing the same, and a printed circuit board including the same.

2. Description of the Related Art

With the development of electronic devices, a printed circuit board has continuously been demanded to have a low weight, a thin thickness, and a small size. In order to satisfy these demands, wirings of the printed circuit board becomes more complex and further densified. These electrical, thermal, and mechanical characteristics requested for the printed circuit board act are important factors.

The printed circuit board is mainly composed of copper for circuit wirings and polymer for interlayer insulation. As compared with copper, the polymer constituting an insulating layer demands several characteristics, such as, coefficient of thermal expansion, glass transition temperature, thickness uniformity, and the like. Particularly, the insulating layer needs to be formed to have a smaller thickness.

The copper-clad laminate (hereinafter, referred to as “CCL”) of the prior art is manufactured as follows. First, varnishes for an insulating layer are mixed in a tank, and then are put into an impregnating bath. Then, a thin cloth type of glass fabric is immersed in the impregnating bath so that the glass fabric is coated with the varnish, and then the thickness of the coated glass fabric is uniformly controlled. Then, this is transferred to a dry stage, and then dried by heat wind or UV, to prepare a prepreg. Copper foils are laminated on both surfaces of the thus prepared prepreg, to manufacture a CCL.

Meanwhile, as the circuit board becomes thinner, thickness characteristics of the circuit board are unstable, resulting in deteriorating characteristics, such as, coefficient of thermal expansion, dielectric constant, dielectric loss, and the like. In addition, the circuit board may be bent at the time of mounting components thereon, and signals may be erroneously transmitted in a high-frequency wave region. Particularly, the method for manufacturing the CCL according to the prior art has a limitation in thinning the CCL. In addition, the thickness of the CCL may not be uniformly maintained and asymmetric prepreg and CCL may not be manufactured.

### SUMMARY OF THE INVENTION

The foregoing problems can be solved by placing a glass fabric between resin-coated copper (hereinafter, referred to as “RCC”) foils, each in which a resin composition for a printed circuit board having excellent heat resistance is coated on one surface of a copper foil, and then performing pressing thereon, to thereby manufacture a copper-clad laminate (CCL), and based on this, the present invention has been completed.

The present invention has been made in an effort to provide a method for manufacturing a CCL for a printed circuit board, capable of being made as a thin substrate while uniformly maintaining thickness quality and allowing both thicknesses thereof to be symmetrical or asymmetrical with respect to a glass fabric.

The present invention also has been made in an effort to provide a CCL where a glass fabric is placed between insulating layers of two independent RCC foils, the insulating layers being symmetrical or asymmetrical with respect to the glass fabric.

The present invention has also been made in an effort to provide a printed circuit board to which the CCCL is applied.

According to one preferred embodiment of the present invention, there is provided a method for manufacturing a copper-clad laminate for a printed circuit board, the method including: forming a first resin coated copper foil (first RCC foil) and a second resin coated copper foil (second RCC foil) by coating an insulating composition on one surface of each of two copper foils to form insulating layers, respectively, followed by drying of the first and second RCC foils; forming a copper-clad laminate (CCL) by laminating and pressing the first RCC foil and the second RCC foil while the insulating layers of the first and second RCC foils face each other and a glass fiber is placed therebetween; and hardening the copper-clad laminate.

The insulating composition may include an epoxy resin, a polyester amide based liquid crystal oligomer, a silica inorganic filler, and a solvent.

The insulating composition may have viscosity of 500 to 1000 cps under conditions of 20 to 25° C. and 100 rpm.

The insulating composition may have flowability of 5 to 70% under conditions of 200 to 300° C. and 0.5 to 5 MPa.

The insulating composition may have a volatile component content of 0.5 to 10 wt. %.

Here, thicknesses of the first RCC foil and the second RCC foil may be symmetrical or asymmetrical.

Here, in the forming of the first RCC foil and the second RCC foil, a thickness of each of the insulating layers may be 100 μm; and, here, after the laminating and pressing, an overall thickness of the insulating layers may be 50 to 200 μm.

Here, after the laminating and pressing, the entire insulating composition may have a content of 40 to 70 vol. % of the overall insulating layers.

The drying of the first and second RCC foils may be repeatedly performed one or more times within ranges of 50 to 150° C. and 3 to 180 minutes in the same or different conditions.

Here, in the forming of the CCL, the laminating and pressing may be repeatedly performed one or more times within ranges of a temperature of 50 to 150° C., surface pressure of 0.1 to 50 MPa, laminating time of 1 second to 1 hour, and a vacuum degree of 10⁻⁵ to 10 torr in the same condition or different conditions.

Here, in the forming of the CCL, the laminating and pressing may be repeatedly performed one or more times within ranges of a temperature of 50 to 150° C., linear pressure of 1 to 500 kgf/cm, laminating time of 1 second to 1 hour, and a vacuum degree of 10⁻⁵ to 10 torr in the same condition or different conditions.

Here, in the forming of the CCL, the hardening may be repeatedly performed one or more times within ranges of a temperature of 50 to 350° C., surface pressure of 0.1 to 50 MPa, hardening time of 10 minutes to 10 hours, and vacuum degree of 105 to 10 torr in the same or different conditions.

Here, in the forming of the CCL, the hardening may be repeatedly performed one or more times within ranges of a temperature of 50 to 350° C., linear pressure of 1 to 500 kgf/cm, hardening time of 10 minutes to 10 hours, and vacuum degree of 10⁻⁵ to 10 torr in the same or different conditions.

According to another preferred embodiment of the present invention, there is provided a copper-clad laminate (CCL) manufactured by placing a glass fabric between insulating layers of two independent resin coated copper (RCC) foils, the insulating layers being symmetrical or asymmetrical with respect to the glass fabric.

According to still another preferred embodiment of the present invention, there is provided a printed circuit board including the copper-clad laminate (CCL) as described above applied thereto.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a flow chart showing a method for manufacturing a copper-clad laminate (CCL) according to the present invention;

FIG. 2 is a cross-sectional view of a first RCC or a second RCC according to the present invention;

FIG. 3 is a state view showing a lamination structure of the first RCC, the second RCC, and a glass fabric;

FIG. 4 is a state view showing a lamination structure of the first RCC, the second RCC, and a glass fabric, for manufacturing an asymmetrical CCL according to the present invention;

FIG. 5 is a state view showing a procedure for manufacturing a CCL in a roll pressing manner, according to the present invention; and

FIG. 6 is a cross-sectional view of a CCL manufactured according to the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

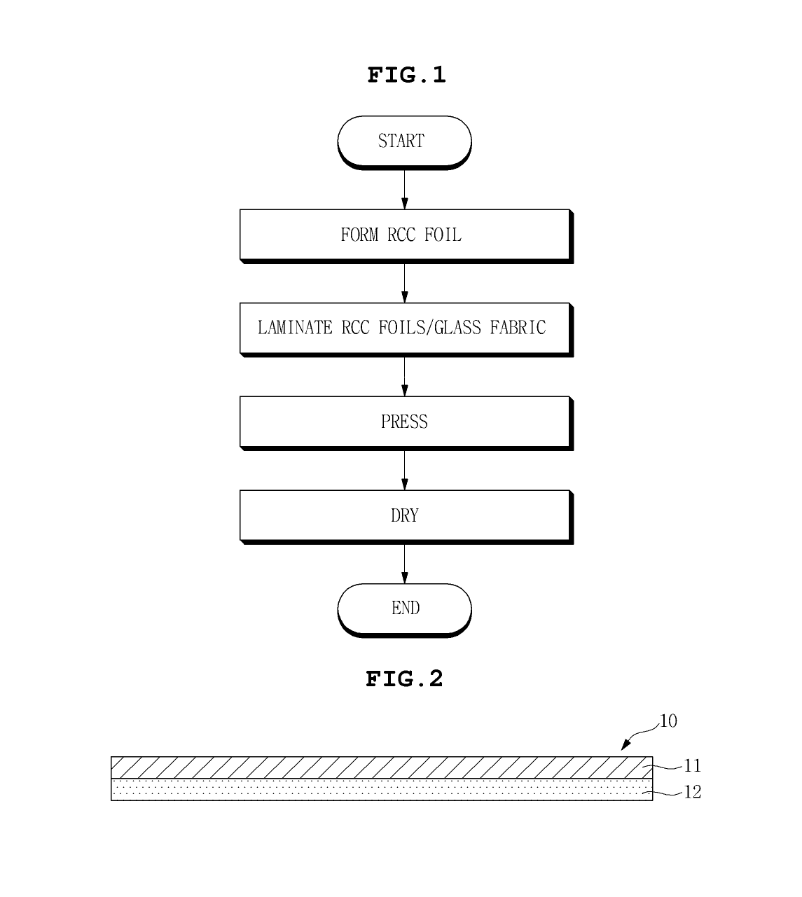

Referring to FIGS. 1 to 6, a copper-clad laminate (CCL) 100 according to the present invention is manufactured by subjecting to a forming step of resin coated copper (CCL) foil 10, and laminating, pressing and drying steps of RCC foils 10 and a glass fabric 20.

Forming Step of RCC Foil

Referring to FIG. 2, the forming step of RCC foil 10 may include coating an insulating composition 12 on a copper foil 11 and drying thereof. Here, the coating of the insulating composition 12 may be carried out by using a comma coater, a die coater, or the like. Above these, any technology that can be generally used in coating may be employed. In addition, as shown in FIG. 4, according to the present invention, RCC foils 10a and 10b having different thicknesses may be formed by controlling the amount of an insulating composition of insulating layers 12a and 12b, which is coated on copper foils 11a and 11b having an identical thickness and different thicknesses, whereby the coefficient of thermal expansion and the insulation degree can be controlled, and thus an application range thereof to a substrate can be widened.

Meanwhile, as the insulating composition used in the present invention, preferable is an insulating composition 12 retaining resistances to pressure and heat generated in the subsequent laminating and pressing steps. This heat-resistant insulating composition preferably includes, for example, an epoxy resin, polyester amide based liquid crystal oligomer, silica inorganic filler, and solvent. In particular, considering heat resistance and dimensional stability, a compound represented by Chemical Formula 1 is more suitable for the polyester amide based liquid crystal to oligomer; a compound represented by Chemical Formula 2 is more suitable for the epoxy resin, and a compound represented by Chemical Formula 3 is more suitable for the silica (SiO₂) inorganic filter. In addition, examples of the solvent may include, considering solubility and miscibility of the resin and other additives used in the present invention, 2-methoxy ethanol, acetone, methyl ethyl ketone, cyclohexanone, ethyl acetate, butyl acetate, cellosolve acetate, propylene glycol monomethyl ether acetate, ethylene glycol monobutyl ether acetate, cellosolve, butyl cellosolve, carbitol, butyl carbitol, xylene, dimethyl formamide, and dimethyl acetamide, but are not particularly limited thereto.

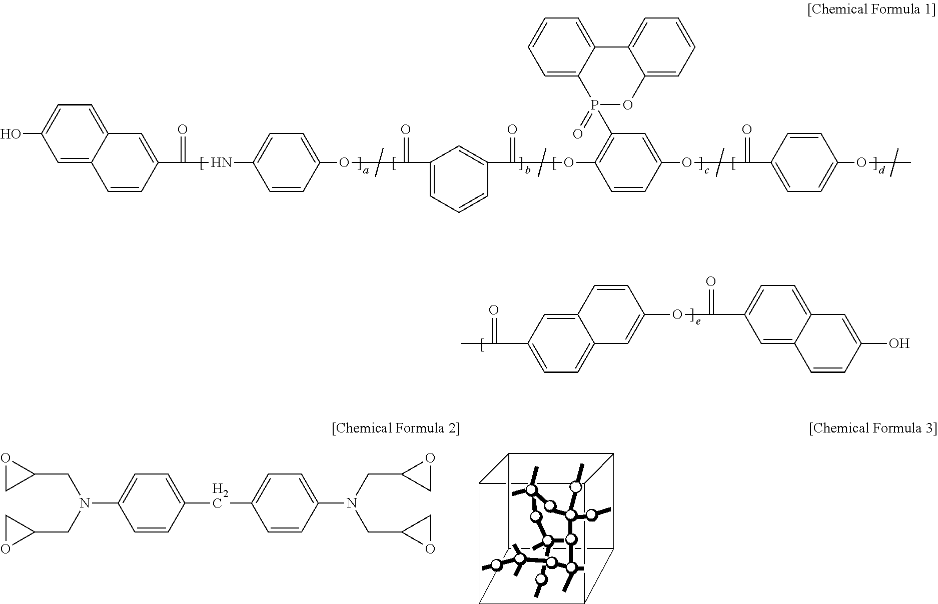

Preferably, the insulating composition may have viscosity of 500 to 1000 cps at room temperature (measured by Brookfield Viscometer under conditions of 20 to 25° C. and 100 rpm), flowability of 5 to 70% under conditions of 200 to 300° C. and 0.5 to 5 MPa, and a volatile component content of 0.5 to 10 wt. %, in view of workability when the insulating composition is coated and dried on the copper foil. In particular, if the volatile component content is below 0.5 wt. %, overdrying and cracks may occur. If the volatile component content is above 10 wt. %, the residual amount of solvent may be large, causing un-hardening and preservation problems.

The thus formed RCC foil 10 is subjected to drying. The drying of the RCC foil 10 may be repeatedly performed one or more times at 50 to 150° C. for 3 to 180 minutes under the same condition or different condition, to thereby maintain the RCC foil 10 in a semi-dried state but not a completely-dried state. The drying may be performed by natural drying, hot-wind drying, or UV drying. The thickness of an insulating layer 12 of one RCC foil after drying is 1 to 100 μm. As described above, the insulating layers 12a and 12b of two RCC foils may have different thicknesses by differentiating the amount of insulating composition.

Laminating and Pressing Steps

Conventionally, a prepreg for a printed circuit board includes a glass fabric, which has a purpose of preventing the separation of an insulating layer from a circuit board containing metal components, which is caused by heat generated at the time of circuit operation, due to a large difference between a coefficient of thermal expansion of an epoxy resin and a coefficient of thermal expansion of a copper foil, a metal component.

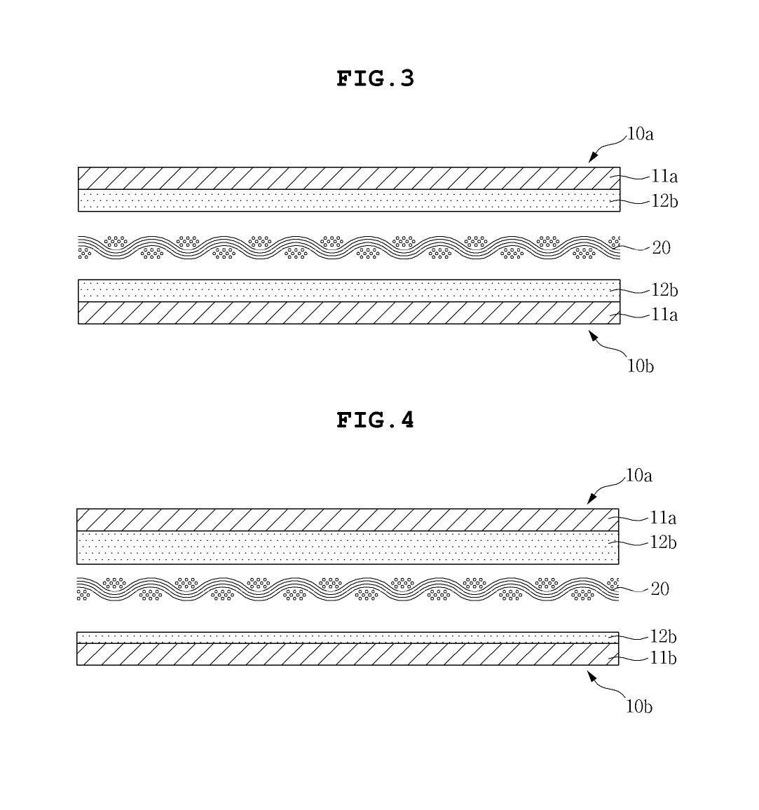

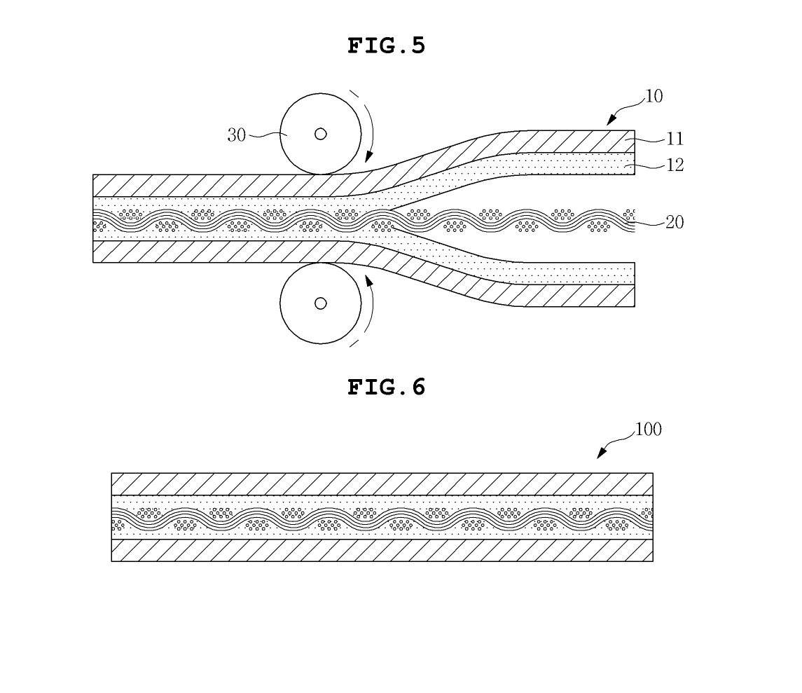

Referring to FIG. 3, in the present invention, the laminating and pressing steps are performed in order to bind the RCC foils 10 and the glass fabric 20. The laminating and pressing steps are performed by allowing the insulating layers 12a and 12b of the two RCC foils (the first RCC foil 10a and the second RCC foil Ob) dried as above to face each other, placing the glass fabric 20 therebetween, and applying pressure from both directions of the RCC foils 10a and 10b. Here, the pressing step may be performed by applying a press pressure (that is, surface pressure) in directions facing each other, or by applying a roll pressure (that is, linear pressure) using two cylindrical pressing rolls 30, as shown in FIG. 5.

In the case of applying the press pressure (that is, surface pressure), preferably, the laminating and pressing steps are repeatedly performed one or more times within ranges of a temperature of 50 to 150° C., a surface pressure of 0.1 to 50 MPa, a laminating time of 1 s to 1 hour, and a vacuum degree of 10⁻⁵ to 10 torr in the same or different conditions, in view of binding the first RCC foil 10a and the second RCC foil 10b. The ranges out of the foregoing conditions may result in reducing the binding strength between the first RCC foil 10a and the second RCC foil 10b.

As shown in FIG. 5, in the case of applying the roll pressure (that is, linear pressure), preferably, the laminating and pressing steps are repeatedly performed one or more times within a temperature of 50 to 150° C., a linear pressure of 0.1 to 500 kgf/cm, a laminating time of 1 s to 1 hour, and a vacuum degree of 10⁻⁵ to 10 torr in the same or different conditions, in view of the same reason as the case where the press pressure is applied.

Hardening Step and Completion of CCL

According to the present invention, the insulating layers are completely hardened by controlling the temperature and pressure, after the laminating and pressing steps, thereby manufacturing a CCL 100 as shown in FIG. 6.

In the case of applying the press pressure (that is, surface pressure), preferably, the hardening is repeatedly performed one or more times within ranges of a hardening temperature of 50 to 350° C., a surface pressure of 0.1 to 50 MPa, a hardening time of 10 minutes to 10 hours, and a vacuum degree of 10⁻⁵ to 10 torr in the same or different conditions, in view of binding the first RCC foil 10a and the second RCC foil 10b.

As shown in FIG. 5, in the case of applying the roll pressure (that is, linear pressure), preferably, the hardening is repeatedly performed one or more times within ranges of a hardening temperature of 50 to 350° C., a surface pressure of 1 to 500 kgf/cm, a hardening time of 10 minutes to 10 hours, and a vacuum degree of 10⁻⁵ to 10 torr in the same or different conditions, in view of binding the first RCC foil 10a and the second RCC foil 10b.

After completing the hardening step, the thickness of the overall insulating layers of the bound first RCC foil 10a and second RCC foil 10b is generally 50 to 200 μm. This means a thickness of the overall insulating layers containing the glass fabric, and a thickness of the residual layers except for the copper foils in the CCL shown in FIG. 6. As described above, the thickness for the insulating layer of each of the first RCC foil 10a and the second RCC foil 10b is 1 to 100 μm. However, in order to obtain a prepreg satisfying appropriate mechanical properties, the thickness of the overall insulating layers after the pressing and hardening steps, while having the glass fabric therebetween, needs to be maintained 50 to 200 μm.

Hereinafter, the present invention will be described in more detail with reference to the following examples, but the scope of the present invention is not limited thereto.

In the present preferred embodiment, the applying of the press pressure (surface pressure) is adopted between the two pressing manners exemplified above. However, the applying of the roll pressure (linear pressure) as shown in FIG. 5 is likely to be more effective for mass-production of the CCLs according the present invention.

### Preparative Example

First, 4-aminophenol 218.26 g (2.0 mol), isophthalic acid 415.33 g (2.5 mol), 4-hydroxy benzoic acid 276.24 g (2.0 mol), 6-hydroxy-2-naphthoic acid 282.27 g (1.5 mol), DOPO-HQ 648.54 g (2.0 mol), and acetic anhydride 1531.35 g (15.0 mol) were added in a 20-L glass reactor. After an inside of the reactor was sufficiently replaced with nitrogen gas, and then the inner temperature of the reactor was raised to 230° C. under the flow of nitrogen gas. The nitrogen gas was circulated for 4 hours while the inner temperature of the reactor was maintained at that temperature. 6-hydroxy-2-naphthoic acid 188.18 g (1.0 mol) for end capping was additively added, and then, acetic acid as a by-product and unreacted acetate anhydride were removed, to prepare a polyester amide based liquid crystal oligomer. The polyester amide based liquid crystal oligomer as a product had a number average molecular weight of about 4000.

### Example 1

A first RCC foil and a second RCC foil were made by coating an insulating composition composed of the liquid crystal oligomer (12 wt. %) obtained in the preparative example above, bisphenol F-based 4-functional epoxy (8 wt. %), a silica inorganic filler (30 wt. %), and dimethyl acetamide (50 wt. %) on two copper foils to have a thickness of 10 μm each. Here, viscosity of the insulating composition had viscosity of about 700 cps (measured by Brookfield viscometer under conditions of 23° C. and 100 rpm), and the drying temperature was 110° C. and the drying time was 20 minutes. The volatile component of a resin layer of each of the RCC foils (by measuring weight before drying and weight after drying while the drying was carried out in an oven at 200° C. for 10 minutes, and then calculating the amount of volatilized solvent) was 7%. In addition, flowability of the resin layer of the RCC (resin flowability measurement: a degree at which a film type resin flows and spreads under conditions of heat of 250° C. and pressure of 3 MPa) was 50%.

After a structure of first RCC foil-glass fabric-second RCC foil was formed, laminating and pressing of the structure were repeatedly performed two times under conditions of a laminating temperature of 90° C., a laminating pressure of 0.45 Mpa, a laminating time of 20 seconds, and a vacuum degree of 10 torr, and then under conditions of a laminating temperature of 90° C., a laminating pressure of 0.48 Mpa, a laminating time of 40 seconds, and a vacuum degree of 10 torr.

Also, hardening of the structure was repeatedly performed two more times under conditions of a hardening temperature of 130° C., a hardening pressure of 2 Mpa, a hardening time of 0.5 hours, and a vacuum degree of 10 torr, and then under conditions of a hardening temperature of 230° C., a hardening pressure of 2 Mpa, a hardening time of 3 hours, and a vacuum degree of 10 torr.

In the thus formed CCL, the thickness of each of the insulating layers was uniform with respect to the glass fabric, and the overall thickness of the insulating layers was about 100 μm.

### Example 2

A first RCC foil and a second RCC foil were made by coating an insulating composition composed of the liquid crystal oligomer (12 wt. %) obtained in the preparative example above, bisphenol F-based 4-functional epoxy (8 wt. %), silica inorganic filler (30 wt. %), and dimethyl acetamide (50 wt. %) on two copper foils to have a thickness of 20 μm and 10 μm, respectively. Here, viscosity of the insulating composition had viscosity of about 700 cps (measured by Brookfield viscometer under conditions of 23° C. and 100 rpm), and the drying temperature was 110° C. and the drying time was 20 minutes. The volatile component of a resin layer of each of the RCC foils (by measuring weight before drying and weight after drying while the drying was performed in an oven at 200° C. for 10 minutes, and then calculating the amount of the volatilized solvent) was 7%. In addition, flowability of the resin layer of the RCC (resin flowability measurement: a degree at which a film type resin flows and spreads under conditions of heat of 250° C. and pressure of 3 MPa) was 50%.

After a structure of first RCC foil-glass fabric-second RCC foil was formed, laminating and pressing of the structure were repeatedly performed two times under conditions of a laminating temperature of 90° C., a laminating pressure of 0.45 Mpa, a laminating time of 20 seconds, and a vacuum degree of 10 torr, and then under conditions of a laminating temperature of 90° C., a laminating pressure of 0.48 Mpa, a laminating time of 40 seconds, and a vacuum degree of 10 torr.

Also, hardening of the structure was repeatedly performed two times under conditions of a hardening temperature of 130° C., a hardening pressure of 2 Mpa, a hardening time of 0.5 hours, and a vacuum degree of 10 torr, and then under conditions of a hardening temperature of 230° C., a hardening pressure of 2 Mpa, a hardening time of 3 hours, and a vacuum degree of 10 torr.

In the thus formed CCL, the thicknesses of the respective insulating layers were about 50 μm and about 57 μm, respectively, with respect to the glass fabric, and the overall thickness of the insulating layers was about 107 μm.

In the present invention, the CCL for a printed circuit board can be manufactured in a thin plate; the CCL is allowed to have a desired thickness or maintain a uniform thickness, thereby achieving stability in thickness quality; and a CCL where both thicknesses are symmetrical or asymmetrical with respect to a glass fabric can be manufactured, thereby widening an application range thereof to a substrate.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A method for manufacturing a copper-clad laminate for a printed circuit board, the method comprising:
forming a first resin coated copper foil (first RCC foil) and a second resin coated copper foil (second RCC foil) by coating an insulating composition on one surface of each of two copper foils to form insulating layers, respectively, followed by drying of the first and second RCC foils;
forming a copper-clad laminate (CCL) by laminating and pressing the first RCC foil and the second RCC foil while the insulating layers of the first and second RCC foils face each other and a glass fiber is placed therebetween; and
hardening the copper-clad laminate.

2. The method as set forth in claim 1, wherein the insulating composition includes an epoxy resin, a polyester amide based liquid crystal oligomer, a silica inorganic filler, and a solvent.

3. The method as set forth in claim 1, wherein the insulating composition has viscosity of 500 to 1000 cps under conditions of 20 to 25° C. and 100 rpm.

4. The method as set forth in claim 1, wherein the insulating composition has flowability of 5 to 70% under conditions of 200 to 300° C. and 0.5 to 5 MPa.

5. The method as set forth in claim 1, wherein the insulating composition has a volatile component content of 0.5 to 10 wt. %.

6. The method as set forth in claim 1, wherein thicknesses of the first RCC foil and the second RCC foil are symmetrical or asymmetrical.

7. The method as set forth in claim 1, wherein in the forming of the first RCC foil and the second RCC foil, a thickness of each of the insulating layers is 100 μm; and wherein after the laminating and pressing, an overall thickness of the insulating layers is 50 to 200 μm.

8. The method as set forth in claim 1, wherein after the laminating and pressing, the entire insulating composition has a content of 40 to 70 vol. % of the overall insulating layers.

9. The method as set forth in claim 1, wherein the drying of the first and second RCC foils are repeatedly performed one or more times within ranges of 50 to 150° C. and 3 to 180 minutes in the same or different conditions.

10. The method as set forth in claim 1, wherein in the forming of the CCL, the laminating and pressing are repeatedly performed one or more times within ranges of a temperature of 50 to 150° C., surface pressure of 0.1 to 50 MPa, laminating time of 1 second to 1 hour, and a vacuum degree of 10⁻⁵ to 10 torr in the same condition or different conditions.

11. The method as set forth in claim 1, wherein in the forming of the CCL, the laminating and pressing are repeatedly performed one or more times within ranges of a temperature of 50 to 150° C., linear pressure of 1 to 500 kgf/cm, laminating time of 1 second to 1 hour, and a vacuum degree of 10⁻⁵ to 10 torr in the same condition or different conditions.

12. The method as set forth in claim 1, wherein in the forming of the CCL, the hardening is repeatedly performed one or more times within ranges of a temperature of 50 to 350° C., surface pressure of 0.1 to 50 MPa, hardening time of 10 minutes to 10 hours, and vacuum degree of 10⁻⁵ to 10 torr in the same or different conditions.

13. The method as set forth in claim 1, wherein in the forming of the CCL, the hardening is repeatedly performed one or more times within ranges of a temperature of 50 to 350° C., linear pressure of 1 to 500 kgf/cm, hardening time of 10 minutes to 10 hours, and vacuum degree of 10⁻⁵ to 10 torr in the same or different conditions.

14. A copper-clad laminate (CCL) manufactured by placing a glass fabric between insulating layers of two independent resin coated copper (RCC) foils, the insulating layers being symmetrical or asymmetrical with respect to the glass fabric.

15. A printed circuit board comprising the copper-clad laminate (CCL) as set forth in claim 14 applied thereto.
